(19) United States
(12) Patent Application Publication
(10) Pub. No.: US 2025/0372949 A1
(43) Pub. Date: Dec. 4, 2025

(54) MID-INFRARED EMITTING QUANTUM CASCADE LASER

(71) Applicant: COMMISSARIAT A L'ENERGIE ATOMIQUE ET AUX ENERGIES ALTERNATIVES, Paris (FR)

(72) Inventors: Maxime LEPAGE, Grenoble (FR); Badhise BEN BAKIR, Grenoble (FR)

(73) Assignee: COMMISSARIAT A L'ENERGIE ATOMIQUE ET AUX ENERGIES ALTERNATIVES, Paris (FR)

(21) Appl. No.: 19/224,463

(22) Filed: May 30, 2025

(30) Foreign Application Priority Data
May 31, 2024 (FR) FR2405732

(51) Int. Cl. H01S 5/12; G01N 21/17; H01S 5/02251; H01S 5/10; H01S 5/34

(52) U.S. Cl. CPC H01S 5/1203; G01N 21/1702; H01S 5/02251; H01S 5/1028; H01S 5/3402; G01N 2021/1704; G01N 2201/06113; H01S 2302/00

(57) ABSTRACT

The invention relates to a quantum cascade laser emitting a TM polarized optical mode with a wavelength between 3 and 15 μm, including a gain medium and a main waveguide. The latter includes a coupling section in contact with the gain medium, comprising a DFB diffraction grating. The coupling section has a width greater than or equal to a minimum width from which an antisymmetric supermode propagating in a laser guiding structure comprising the gain medium and the main waveguide, has a confinement factor in an active region of the gain medium strictly greater than those of the optical modes likely to be guided by the guiding structure. The main waveguide includes a core based on atoms from column IV A of the periodic table of elements and a SiN or chalcogenide confinement sublayer.

### CROSS REFERENCE TO RELATED APPLICATIONS

This application claims the priority benefit of French patent application number 24/05732, filed on May 31, 2024, entitled “Quantum cascade laser emitting in the mid-infrared range”, which is hereby incorporated by reference to the maximum extent allowable by law.

### TECHNICAL FIELD

The field of the invention is that of quantum cascade lasers emitting in the mid-infrared, for example in the wavelength range between 3 μm and 15 μm. The invention relates, for example, to a gas sensor comprising such a quantum cascade laser.

### PRIOR ART

Quantum cascade lasers are commonly used in gas detection systems, such as a non-dispersive infrared gas sensor or a photoacoustic spectrometer. Each quantum cascade laser typically emits a light flux at a wavelength absorbed by a gas intended to be detected. The wavelength range of interest for this application is mid-infrared ranging from 3 μm to 15 μm, and more specifically the wavelength range ranging from 4 μm to 15 μm.

There are distributed feedback type quantum cascade lasers, known as DFB (for Distribute Feedback). A DFB quantum cascade laser generally comprises a gain medium made of III-V materials. The gain medium includes an active region composed of alternating quantum wells and barriers, for example made of InGaAs for the wells and AlInAs for the barriers. The gain medium has geometric dimensions and refractive indices enabling the guiding of a laser optical mode at an emission wavelength along an optical axis of the gain medium. During operation, the energy difference between two conduction bands of two adjacent wells of the active region is such that an electron emits a photon at the emission wavelength when passing from one to the other, so as to excite the laser optical mode. Quantum wells extend parallel to a plane containing the optical axis. The photon is polarized perpendicularly to the quantum wells, so is the laser optical mode.

In a section plane perpendicular to the quantum wells, the laser mode is guided by a lower confinement layer and an upper confinement layer arranged on either side of the active region. The lower and upper confinement layers each have a refractive index lower than a minimum refractive index of the active region. They are made of a semiconductor material doped to transport electrons to or from the active region. They therefore have a dual function and are generally made of N-doped InP.

A grating satisfying the Bragg condition at the emission wavelength is structured in or on the gain medium so as to diffract the laser optical mode to make it travel back and forth within the gain medium. A laser beam is emitted by a side face of the gain medium orthogonal to the quantum wells and to the optical axis. It has a dimension greater than or equal to the emission wavelength at the side face. The gain medium may have cross-sectional dimensions in the order of twice the emission wavelength. The length of the gain medium along the optical axis is sufficient to obtain the desired laser beam power.

For specific applications, such as gas detection, it is often necessary to optically couple one or more quantum cascade lasers to an integrated photonic circuit that performs optical functions. For a photoacoustic spectrometer, it may for instance be necessary to multiplex the laser beams emitted at different emission wavelengths by a plurality of quantum cascade lasers, at the input of a chamber containing a gas to be analyzed. Multiplexing can be carried out by an Arrayed Waveguide Grating (AWG).

A conventional integrated photonic circuit includes silicon waveguides encapsulated in silicon oxide layers. However, silicon oxide transmits little or no light in the wavelength range of interest. It is therefore not possible to optically couple a quantum cascade laser emitting a laser beam in the mid-infrared to a conventional photonic circuit.

It is known to couple a quantum cascade laser to a photonic circuit via an edge coupler of the photonic circuit, i.e. via a side face of the edge coupler and of a photonic chip comprising the photonic circuit. The edge coupler includes a waveguide optically coupled to other waveguides and/or optical components of the photonic circuit. All the waveguides of the photonic circuit are made of the same material(s). Since the laser beam emitted in the wavelength range of interest is large, it is necessary to use waveguides with a low refractive index contrast between their core and confinement layers. All the waveguides of the photonic circuit generally have a germanium core and one or more silicon-germanium confinement layers. These materials are not standard in the field of integrated photonics. Moreover, the low refractive index contrast implies that the waveguides are large and gently curved. The photonic chip is consequently large. When it forms part of a gas sensor, the chamber containing the gases to be analyzed is sized in proportion to the size of the waveguides. It is therefore also large.

There is thus a need to optically couple quantum cascade lasers emitting in the wavelength range of interest to a photonic chip comprising waveguides with a higher refractive index contrast and transparent at wavelengths in the mid-infrared range.

In the field of chip-to-chip data communications, known as “datacoms”, and that of telecommunications, known as “telecoms”, it is known to optically couple a gain medium made of III-V materials to a conventional photonic circuit by evanescent coupling with a silicon main waveguide of the photonic circuit. The main waveguide includes a grating in a coupling section of the main waveguide, capable of achieving distributed feedback in the gain medium at an emission wavelength within a range of photoluminescence wavelengths of the gain medium.

The main waveguide further comprises a modal transition section ensuring an adiabatic coupling of the laser mode to a propagation section of the main waveguide. The propagation section is not facing the gain medium. It is optically coupled to one or more components of the photonic circuit. The photonic circuit is part of a photonic chip. The assembly comprising the gain medium and the main waveguide are elements of a hybrid laser integrated into the photonic chip, i.e. the hybrid laser is an integral part of the photonic chip.

An example of a laser integrated into a photonic chip that is particularly advantageous for “datacom” or “telecom” applications is described in EP3793045 A1. Herein, the gain medium comprises a stack of quantum wells interposed between an upper P-doped confinement layer, and a lower N-doped confinement layer. The gain medium is bonded to a substrate extending along a main plane. Quantum wells extend parallel to the main plane. An optical waveguide includes a coupling section facing the gain medium, a propagation section that is not facing the gain medium, and a modal transition section extending from the coupling section to the propagation section. The waveguide extends parallel to the main plane. A silicon oxide bonding layer separates the gain medium from the coupling section. The coupling section comprises a diffraction grating.

During operation, an electron recombines with a hole in a quantum well to emit a polarized photon parallel to the quantum wells and the main plane. The waveguide is sized with respect to the gain medium such that the polarized photon excites an antisymmetric, or odd, supermode of the structure composed of the gain medium and the coupling section. Given the polarization of the photon, the antisymmetric supermode is of the transverse electric (TE) type. The modal transition section gradually narrows from the coupling section to the propagation section so as to achieve a modal conversion between the antisymmetric supermode and an optical mode propagating in the propagation section. The optical mode therefore has the same polarization as the antisymmetric supermode, i.e. a transverse electric (TE) polarization.

### DESCRIPTION OF THE INVENTION

The object of the invention is to at least partly overcome the drawbacks of the prior art, and more specifically to provide an integrated quantum cascade laser, the laser emitting a transverse magnetic (TM) polarized optical mode at a wavelength λ between 3 μm and 15 μμm.

For this purpose, the object of the invention is a quantum cascade laser for emitting a transverse magnetic polarized optical mode at a wavelength λ between 3 μm and 15 μm, comprising a semiconductor gain medium comprising an active region, a main waveguide extending parallel to the active region. The main waveguide comprises a coupling section in contact with the gain medium, comprising a diffraction grating configured to generate distributed feedback in the gain medium at the wavelength λ, and a propagation section separated from the gain medium, configured to guide the optical mode. The quantum cascade laser is such that the coupling section has a width W greater than or equal to a minimum width Wₘᵢₙ from which an antisymmetric supermode propagating in a guiding structure of the quantum cascade laser that comprises the gain medium and the main waveguide, has a confinement factor in the active region strictly greater than the confinement factors in the active region of the optical modes likely to be guided by the guiding structure. The quantum cascade laser is such that the main waveguide comprises a core made of a material based on Group IV A atoms of the Periodic Table of Elements and a silicon nitride or chalcogenide confinement sublayer, on a side of the main waveguide opposite to the gain medium.

Some preferred but non-limiting aspects of this quantum cascade laser are as follows.

The main waveguide may further comprise a modal transition section in contact with the gain medium, extending from the coupling section to the propagation section. The modal transition section may gradually narrow from the coupling section to the propagation section so as to cause a modal conversion between the antisymmetric supermode and an optical mode.

The gain medium may comprise a lower semiconductor portion in contact with the main waveguide and an upper semiconductor portion, both N-doped. The active region may be interposed between the lower and upper semiconductor portions.

The active region and the upper semiconductor portion may each and together have a rectangular parallelepiped shape.

The diffraction grating may include teeth, each with a depth hr, the width W and the depth hr can be such that the diffraction grating has a coupling strength Kᵣ between 5 cm⁻¹ and 100 cm⁻¹, preferably between 10 cm⁻¹ and 28 cm⁻¹.

The diffraction grating may include teeth, each with a depth hᵣ, the depth hᵣ can be greater than a minimum depth h_{r,min} enabling a variation of a coupling strength Kᵣ of the diffraction grating as a function of hᵣ to be contained within an acceptable variation range determined to guarantee compliance with a specification of the quantum cascade laser.

A gas sensor may comprise a photonic chip, a chamber optically coupled to the photonic chip, the photonic chip may comprise a quantum cascade laser according to any one of the preceding characteristics, integrated into the photonic chip.

The quantum cascade laser may be an element of an array of a plurality of quantum cascade lasers according to any one of the preceding characteristics, each quantum cascade laser of the array can be configured to emit an optical mode at a wavelength λᵢ different from the wavelengths of the optical modes emitted by the other quantum cascade lasers of the array.

The photonic chip may include a wavelength multiplexer and a structured layer. Each propagation section of a quantum cascade laser of the array may be optically connected to a separate input of the multiplexer. The multiplexer may comprise an output waveguide optically coupled to each of the inputs of the multiplexer, and to the chamber. The structured layer May comprise the multiplexer, the output waveguide and each of the main waveguides of the quantum cascade lasers of the array.

The structured layer can further comprise at least a portion of the chamber.

The chamber may be a differential Helmholtz resonant photoacoustic cell.

### BRIEF DESCRIPTION OF THE DRAWINGS

Other aspects, aims, advantages and features of the invention will become apparent upon reading the following detailed description of preferred embodiments thereof, provided as a non-limiting example with reference to the appended drawings wherein:

FIG. 1A is a schematic top view of a quantum cascade laser according to the invention;

FIG. 1B is a schematic longitudinal cross-sectional view of the laser;

FIG. 1C is a schematic cross-sectional view of the laser;

FIG. 2 is a schematic top view of a gas sensor using an array of quantum cascade lasers according to the invention;

FIG. 3 is a graph showing changes in effective refractive indices of transverse magnetic (TM) modes guided in respective waveguides, as a function of the width of the waveguides;

FIG. 4 is a graph showing changes in the confinement of supermodes of the laser, as a function of the width of a main waveguide of the laser;

FIG. 5 is a graph showing changes in the coupling strength of supermodes of the laser with a laser diffraction grating, as a function of the width of the main waveguide;

FIG. 6 is a graph showing changes in the coupling strength of an antisymmetric supermode of the laser with the diffraction grating, as a function of a tooth depth of the diffraction grating.

### DETAILED DISCLOSURE OF PARTICULAR EMBODIMENTS

In the figures and in the following description, the same reference numerals represent identical or similar elements. In addition, the various elements are not shown to scale to ensure that the figures are clear. Moreover, the various embodiments and variants are not mutually exclusive and may be combined. Unless stated otherwise, the terms “substantially”, “about”, “in the order of” mean within a 10% margin, and preferably within a 5% margin. Moreover, the terms “between . . . and . . . ” and equivalents mean that the bounds are included, unless stated otherwise.

The invention relates to a quantum cascade laser emitting a transverse magnetic polarized optical mode at a wavelength λ within the wavelength range of interest. It comprises a semiconductor gain medium in contact with a main waveguide of the laser. The main waveguide has a coupling section comprising a diffraction grating, in contact with the gain medium. It has a propagation section that is not facing the gain medium and a modal transition section interposed between the coupling section and the propagation section.

The coupling section and the gain medium have dimensions for guiding a supermode at the wavelength λ in a guiding structure comprising the gain medium and the coupling section. A pitch of the diffraction grating satisfies the Bragg condition for the wavelength λ. It is arranged relative to the gain medium in such a way as to create an optical cavity by a distributed feedback phenomenon. Thus, the gain medium is not separated from the coupling section by a bonding layer, and the quantum cascade laser is an integrated DFB laser, not comprising an absorbent layer in its optical cavity.

The coupling section also has a width greater than a minimum width identified by the inventors from which the supermode is an antisymmetric supermode. This ensures a good Side Mode Suppression Ratio (SMSR).

In the description, ‘symmetric supermode’ and ‘antisymmetric supermode’ are given their common meanings in the technical field. For the sake of clarity, however, it should be noted that an antisymmetric supermode, sometimes also called odd supermode, is a particular optical mode propagating along an optical axis in a guiding structure including two waveguides parallel to each other, such that, in any plane orthogonal to the optical axis, the electric field of the optical mode in one of the waveguides is phase-shifted by IT with respect to the electric field of the optical mode in the other waveguide. A symmetric supermode, also sometimes called even supermode, is a particular optical mode propagating along an optical axis in a guiding structure including two waveguides parallel to each other, such that, in any plane orthogonal to the optical axis, the electric field of the optical mode in one of the waveguides is in phase with the electric field of the optical mode in the other waveguide.

The SMSR (Side Mode Suppression Ratio) of a distributed feedback (DFB) laser is a measure of the laser's ability to suppress lateral modes relative to the main mode of laser emission. It is equal to the ratio of the intensity of the main mode to the intensity of the highest intensity lateral mode. It is usually expressed in decibels (dB).

Throughout the description, a waveguide is a single-mode or multi-mode waveguide capable of confining light, as opposed to optical guides within which light propagates by total internal reflection. Without further clarification, a waveguide can be of any type. It can be, for example, a ribbon, edge or planar guide. A waveguide has a core and, optionally, one or more confinement layers surrounding the core so as to be in physical contact with the core. A contrast or variation in refractive indices between the core on the one hand and the confinement layer(s) or a gas or vacuum on the other, allows light to be confined. The waveguides are marked by their cores in the figures. Similarly, without further precision, a refractive index of a waveguide is a refractive index of the core of the waveguide; a distance separating two waveguides is the distance separating the cores of the respective waveguides; the material of a waveguide is the material of the core of the waveguide; when a waveguide extends in a direction, it is understood that the core of the waveguide extends in that direction; when a waveguide is in contact with a layer, it is understood that the core of the waveguide is in contact with the layer.

Here and for the following description, layer is understood as being an area consisting of one or more sub-layers of a material the thickness of which along a z-axis is less, for example ten times or even twenty times, than the longitudinal width and length dimensions thereof in an xy plane perpendicular to the z-axis. A layer may be structured. When it consists of a plurality of sub-layers, the sub-layers may be made from different materials. The sub-layer or sub-layers extend(s) in planes substantially parallel to the xy plane. Where a layer is of a particular type of material or of a particular material, it may comprise a plurality of sub-layers, all of which are of the type of material or of the material respectively.

Throughout the description, two optical components are said to be “optically coupled” if an optical mode can propagate at least partly in the two optical components, optionally via intermediate optical components. The coupling can be done in various ways, for example via direct coupling, a diffraction grating, or adiabatic or evanescent or directional coupling, etc.

Specific embodiments will be described relating to an integrated DFB quantum cascade laser. However, these embodiments may be adapted to other types of integrated lasers, such as a DBR (or Distributed Bragg Reflector) quantum cascade laser.

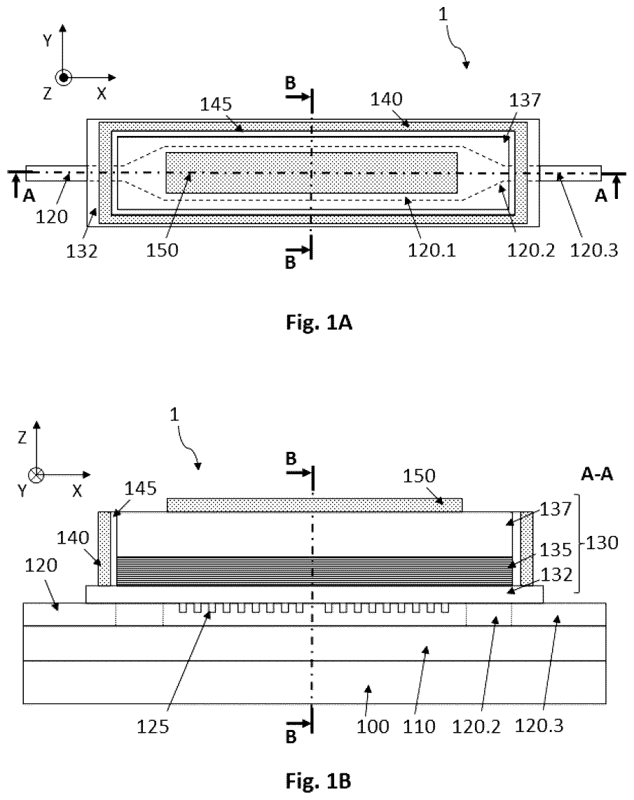

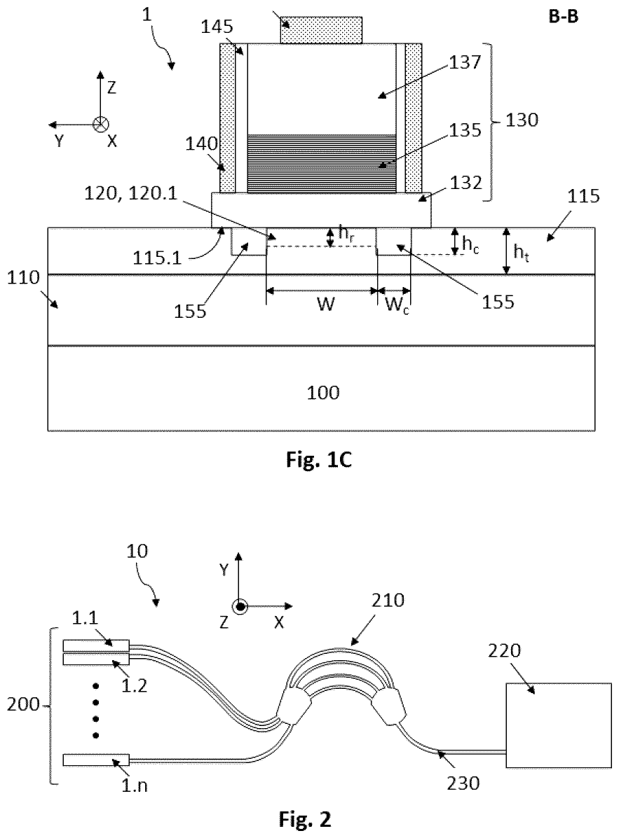

FIGS. 1A, 1B and 1C are views of a quantum cascade laser 1 according to the invention. FIG. 1A is a plan view showing the section plane A-A of FIG. 1B, and the section plane B-B of FIG. 1C.

The quantum cascade laser 1 is configured to emit a polarized optical mode at a wavelength λ. It includes a substrate 100, a main waveguide 120, and a gain medium 130. The substrate 100 has a substantially flat upper face.

Herein and for the remainder of the description, an orthogonal three-dimensional direct reference point (X, Y, Z) is defined, wherein the axes X and Y form a plane parallel to the upper face of the substrate 100, the axis X being oriented in the section plane A-A, and wherein the axis Z is oriented substantially orthogonally to the upper face of the substrate 100, from the upper face to the gain medium 130. In the following description, the terms “vertical” and “vertically” are understood as being relative to an orientation substantially parallel to the Z-axis, and the terms “horizontal” and “horizontally” as being relative to an orientation substantially parallel to the plane (X, Y). Furthermore, the terms “lower” and “upper” are understood to be relative to an increasing positioning when moving away from the substrate 100 along the +Z direction. The term “side” refers to an orientation substantially parallel to the Z axis.

The substrate 100 may be derived from a plate made of a semiconductor material, after possibly having undergone a cutting and/or thinning step. In this example, the substrate 100 is made of silicon.

A lower encapsulation layer 110 is in contact with the upper face of the substrate 100. On a side opposite the substrate 100, it has a substantially flat upper face parallel to the upper face of the substrate 100. The main waveguide 120 extends along a first axis on the upper face of the lower encapsulation layer 110, in contact with a confinement sublayer of the lower encapsulation layer 110. Here, the first axis is straight and parallel to X. In this example, the section plane B-B is a plane of symmetry of the main waveguide 120.

The confinement sub-layer is made of a transparent material at wavelength A. It is, for example, made of a dielectric material. The lower encapsulation layer 110 may or may not comprise additional sub-layers. Where applicable, additional sub-layers may be of any kind. In this example, the confinement sub-layer is silicon nitride (SiN) or an amorphous phase chalcogenide. Here, the lower encapsulation layer 110 comprises an additional sub-layer in contact with the confinement sub-layer and the substrate 100, made of silicon oxide.

The main waveguide 120 is made of a transparent material at the wavelength A, for example of a semiconductor material whose gap energy is greater than the photon energy at the wavelength A. The semiconductor material may be based on atoms from column IV A of the periodic table of elements, i.e. it comprises at least 90% of atoms from column IV A, preferably at least 99%. It may, for example, be silicon, silicon-germanium or germanium. The main waveguide 120 is herein a part of a silicon structured layer 115, which is the conventional material used in silicon photonics in the “datacom” or “telecom” field. It has a thickness measured parallel to the Z axis, preferably constant, between 0.5 μm and 5 μm, for example equal to 2.6 μm. In this example, the main waveguide 120 is a ridge guide. Here, the ridge is at least partially delimited laterally, in a plane parallel to the plane (X, Y) by two elongated cavities 155.

The gain medium 130 faces the elongated cavities 155. The elongated cavities 155 extend parallel to the plane (X, Y), preferably beyond two side faces of the gain medium 130, opposite and perpendicular to the X axis. It is in contact with bearing surfaces 115.1 of the structured layer 115, located on either side of the main waveguide 120. The elongated cavities 155 extend deep into the structured layer 115 from the bearing surfaces 115.1, over a substantially constant depth h_{c}. They have a width W_{c} measured parallel to the plane (X, Y) and perpendicular to the first axis. They are filled with a transparent material at the wavelength λ, with a refractive index strictly lower than a refractive index of the main waveguide 120. In this example, they are filled with air.

The main waveguide 120 includes a coupling section 120.1, a modal transition section 120.2, and a propagation section 120.3. The coupling section 120.1 has a substantially flat upper face parallel to the plane (X, Y). It is in contact with the gain medium 130 over its entire upper face. It has two opposite sides parallel to the first axis, here substantially orthogonal to the plane (X, Y). The upper face of the coupling section 120.1 joins the sides together. The coupling section 120.1 has a width W measured parallel to the Y axis. The widths W and W_{c}, as well as the respective materials of the main waveguide 120 and the elongated cavities 155 allow light to be confined at the wavelength A. Here, the width W is the width of the ridge of the main waveguide 120 at the coupling section 120.1. It is equal to the distance between the two opposite sides. In this example, the width W is substantially constant and equal to the distance separating the elongated cavities 155.

The propagation section 120.3 has dimensions allowing the propagation of the polarized optical mode. It is separated from the gain medium 130, i.e. the gain medium 130 does not cover at least part of the propagation section 120.3, and is therefore not in contact with it at this part.

The modal transition section 120.2 extends parallel to the plane (X, Y) from the coupling section 120.1 to the propagation section 120.3. In a plane parallel to the plane (X, Y), the modal transition section 120.2 gradually narrows from the coupling section 120.1 to the propagation section 120.3. Preferably, it has a horizontal width equal to W at a proximal position in contact with the coupling section 120.1. It at least partially faces the gain medium 130. The propagation section 120.3 and the modal transition section 120.2 preferably have identical horizontal widths at a distal position of the modal transition section 120.2 in contact with the propagation section 120.3.

The gain medium 130 extends along a second axis parallel to the first axis and the plane (X, Y). The first and second axes define a plane coplanar with the section plane A-A. The section plane A-An is, in this example, a plane of symmetry of the main waveguide 120 and the gain medium 130. In this example, the section plane B-B is a plane of symmetry of the gain medium 130.

The gain medium 130 includes a lower semiconductor portion 132, an upper semiconductor portion 137 and an active region 135 interposed between the lower and upper semiconductor portions 132, 137. The active region 135 includes quantum wells extending parallel to the plane (X, Y). The lower and upper semiconductor portions 132, 137 are N-doped here. They are made of a crystalline semiconductor material, in this example indium phosphide (InP). Here, the active region 135 and the upper semiconductor portion 137 have, substantially, each and together, a rectangular parallelepiped shape. They have a width Wₐ measured parallel to the Y axis.

The active region 135 here partially covers the lower semiconductor portion 132. Preferably, the lower semiconductor portion 132 fully covers the portion of the elongated cavities 155 facing the gain medium 130. A lower electrode 140 is in contact with an upper surface of the lower semiconductor portion 132, not covered by the active region 135. Here, the lower electrode 140 surrounds the active region 135 and the upper semiconductor portion 137. It is electrically isolated from the active region 135 and the upper semiconductor portion 137 by an insulating coating 145 interposed between on one side the lower electrode 140 and on the other side, the active region 135 and the upper semiconductor portion 137. The insulating coating 145 is advantageously a passivation layer for the active region 135 and/or the upper semiconductor portion 137.

An upper electrode 150 is in contact with an upper face of the upper semiconductor portion 137. The lower electrode 140 and the insulating coating 145 are, in this case, flush with the upper face of the upper semiconductor portion 137. The lower and upper electrodes 140, 150 are made of an electrically conductive material, for example metal.

The active region 135 is preferably an alternation of quantum wells and barriers, for example between 20 and 50 wells inserted between two barriers. The wells may be made of InGaAs combined with barriers made of AlInAs, or AlAsSb. Alternatively, the wells may be made of InAs with barriers made of AlSb, and preferably a lower semiconductor portion 132 and/or an upper semiconductor portion 137 made of InAs or GaAs. In all cases, two or more wells (barriers) may be made of the same semiconductor alloy but have different atomic concentrations of an element in the alloy. For example, the active region 135 has a length along the X axis between 0.5 mm and 3 mm. For example, it has a height measured along the Z axis between 1.2 μm and 3 μm. It preferably has a width less than or equal to 4λ. Preferably, the width is greater than or equal to λ.

The lower semiconductor portion 132 has a thickness sufficiently small to allow evanescent coupling and sufficiently large for good mechanical strength in vertical alignment with the elongated cavities 155. It may be between λ/10 and λ/5, for example equal to 350 nm when the wavelength λ is equal to 4.5 μm.

The upper semiconductor portion 137 has a sufficient thickness so that, in operation, a

cavity mode of the quantum cascade laser 1, amplified by the gain medium 130, does not interact with the upper electrode 150. For example, it has a thickness between 80 /4 and λ.

The coupling section 120.1 includes a diffraction grating 125. The diffraction grating 125 is a periodic grating satisfying the Bragg condition at the wavelength λ. It may comprise a phase jump in a central region of the diffraction grating 125, for example equal to π or π/2. The diffraction grating 125 is configured to generate distributed feedback in the gain medium 130, i.e. a mode or supermode at the wavelength A guided by the gain medium 130, interacting with the diffraction grating 125, partly makes back-and-forth movements over a length of the gain medium 130 defining an optical cavity of the quantum cascade laser 1.

In this example, the diffraction grating 125 includes a succession of teeth extending perpendicular to the first axis, preferably over the entire width W of the coupling section 120.1. Each tooth is substantially shaped like a rectangular parallelepiped. They extend deep into the coupling section 120.1, from the upper face of the coupling section 120.1, over a depth hᵣ, which may be equal to h_{c}. In FIG. 1C, a bottom edge of a tooth is shown with dashed lines.

The width W of the coupling section 120.1 is greater than or equal to a minimum width Wₘᵢₙ from which an antisymmetric supermode propagating in a guiding structure comprising the gain medium 130 and the main waveguide 120, has a confinement factor in the active region 135 strictly greater than the confinement factors in the active region 135 of the optical modes likely to be guided by the guiding structure.

In operation, the energy difference between the conduction bands of two contiguous quantum wells is equal to the energy of a photon at the wavelength A. Thus, an incident photon from the antisymmetric supermode causes an electron to pass between the two quantum wells. An additional photon is then emitted by a stimulated emission phenomenon. The additional incident photons have the same energy, the same phase and the same polarization direction, perpendicular to the quantum wells.

The antisymmetric supermode is guided by the guiding structure. It is gradually diffracted by the diffraction grating 125 so as to make back and forth movements over a length of the guiding structure defining the optical cavity. The modal transition section 120.2 gradually narrows from the coupling section 120.1 to the propagation section 120.3 so as to transfer part of the energy from the antisymmetric supermode to the polarized guided mode, guided by the propagation section 120.3. Thus, the modal transition section 120.2 has a modal conversion function between the antisymmetric supermode and the polarized guided mode. Here, the modal transition section 120.2 is involved in the adiabatic coupling between the antisymmetric supermode and the polarized optical mode. The polarized guided mode has its polarization oriented in the same direction as that of the antisymmetric supermode, so it is a transverse magnetic (TM) optical mode.

A decrease in the thickness of the lower semiconductor portion 132 makes it possible to reduce the distance separating the proximal and distal positions of the modal transition section 120.2, and thus obtain a more compact quantum cascade laser 1. An increase in the thickness of the lower semiconductor portion 132 makes it possible to decrease its electrical resistance and to reduce the heating of the quantum cascade laser 1.

FIG. 2 is a schematic view of a gas sensor 10 including a photonic chip and a chamber 220 containing a gas to be analyzed.

The photonic chip integrates an array 200 of at least one quantum cascade laser 1 such as that described in connection with FIGS. 1A, 1B and 1C, and a photonic circuit. In FIG. 2, the array 200 includes an integer number n greater than or equal to 3 of quantum cascade lasers 1.i. Here, only the first, second and nth quantum cascade lasers 1.1, 1.2, 1.n are shown. In this example, each quantum cascade laser 1.i emits a TM optical mode at a wavelength λᵢ different from the wavelengths of the optical modes emitted by the other quantum cascade lasers.

The substrate 100, the lower encapsulation layer 110 and the structured layer 115 of a quantum cascade laser 1.i of the array 200 are common to all quantum cascade lasers 1.i, and extend to the entire photonic chip, so that they are elements of the photonic chip that do not need to be distinguished.

The photonic chip comprises a wavelength multiplexer 210, formed, in part or in whole, in the structured layer 115; i.e., the structured layer 115 comprises part or all of the multiplexer 210. Each propagation section 120.3 of a quantum cascade laser 1.i is optically connected to a separate input of the multiplexer 210. The multiplexer 210 is here an Arrayed Waveguide Grating (AWG).

The multiplexer 210 has an output waveguide 230 optically coupled to each of the inputs of the multiplexer 210 and, therefore, to each of the quantum cascade lasers 1. The output waveguide 230 is also optically coupled to the chamber 220. Thus, all TM optical modes emitted by the quantum cascade lasers 1.i of the array 200 are combined in the output waveguide 230 and propagate to the chamber.

The gas sensor 10 further comprises means for detecting and/or measuring a photon absorption by the gas at one or more wavelengths A, and/or an acoustic wave generated by the absorption by the gas of one or more TM optical modes emitted by the array 200 of quantum cascade lasers 1. This allows gas detection or gas concentration measurement to be performed. The gas sensor 10 may, for example, be a non-dispersive infrared gas sensor or a photoacoustic spectrometer, for example such that the chamber 220 is a differential Helmholtz resonant photoacoustic cell.

In this example, the structured layer 115 is made of silicon. The lower encapsulation layer 110 has a silicon nitride (SIN) or chalcogenide confinement sub-layer. In this way, the waveguides of the photonic chip have a high refractive index contrast, and therefore small dimensions and possibly small bending radii. The photonic chip in the gas sensor is therefore compact. The structured layer 115 and/or at least one quantum cascade laser 1 of the array 200 can also be encapsulated on a side opposite the lower encapsulation layer 110 by an upper encapsulation layer, for example of silicon nitride or of an amorphous phase chalcogenide.

Preferably, the main waveguides 120 of the quantum cascade lasers 1.i all have the same height equal to a common guide height. Advantageously, the arrayed waveguide grating (AWG) 210 and the output waveguide 230 have heights equal to the common guide height. This makes the photonic chip easier to manufacture.

The array 200 of quantum cascade lasers 1.i is integrated into the photonic chip, so the gas sensor 10 is compact. Preferably, the chamber 220 comprises a part of the structured layer 115, so as to be integrated with the photonic chip. As a result, the dimensions of the gas sensor are further reduced. For example, it may have a footprint smaller than a rectangle with sides measuring 0.75 cm by 2 cm.

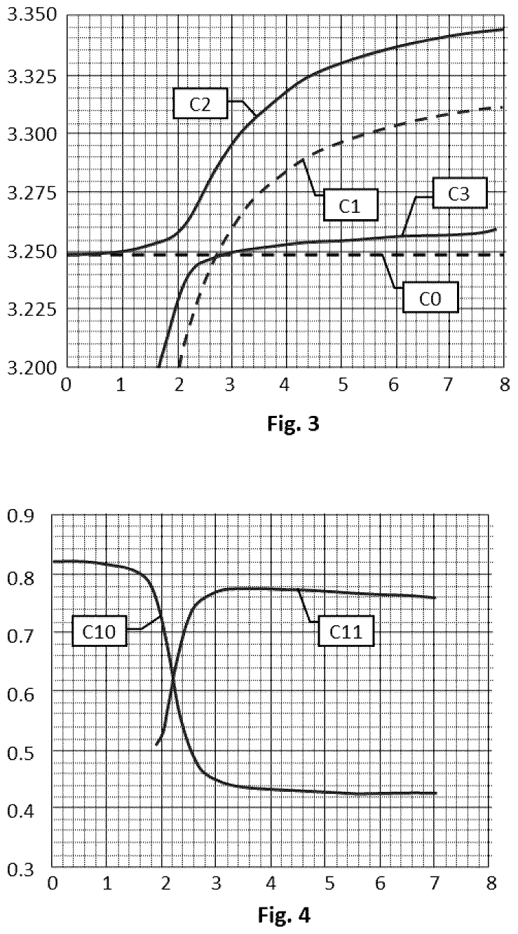

Now, a parametric study that can be used to optimize a quantum cascade laser 1 or an array 200 of quantum cascade lasers 1.i according to the invention will be described in connection with FIGS. 3 to 6.

A first step of determining a thickness hₜ of the structured layer 115, measured parallel to the Z axis, will first be described.

In a first step, the width Wₐ of the active region 135 and of the upper semiconductor portion 137 is set to a value compatible with the propagation of an optical mode in the gain medium 130 at the desired emission wavelength λ. Here, λ is equal to 4.5 μm and Wₐ is fixed at 10 μm.

In a second step, an aspect ratio of the main waveguide 120 is set. In this specific study, the main waveguide 120 is a ridge waveguide. It has a base and a ridge. The ridge is a portion of the main waveguide 120 elevated from the base. It is delimited by elongated cavities 155. The thickness hₜ is equal to the sum of the base and ridge thicknesses.

The elongated cavities 155 are intended here to collect reaction products generated by direct bonding of the gain medium 130 to the main waveguide 120. They are filled with air. The height h_{c} is fixed at 2 thirds (⅔) of the total thickness hₜ of the structured layer 115.

Throughout this study, the main waveguide 120 is made of silicon. The lower encapsulation layer 110 is made of silicon nitride (SiN).

The effective refractive index of a first fundamental TM optical mode of the coupling section 120.1, in the absence of the gain medium 130, is then determined for a plurality of thicknesses of the structured layer 115 and a plurality of widths W of the ridge of the coupling section 120.1. The value of the minimum thickness h_{t,min} of the structured layer 115 is identified beyond which the effective refractive index of the first fundamental TM optical mode is greater than or equal to the effective refractive index of a second fundamental TM optical mode guided by the gain medium 130 in the absence of the main waveguide 120, for a width W less than or equal to a maximum width W^{max} achievable by the ridge. Wₘₐₓ is equal to 2*Wₐ.

A thickness hₜ of the structured layer 115 strictly greater than h_{t,min}, preferably greater than 1.1.h_{t,min}, or even greater than 1.2.h_{t,min} is selected for the following steps of the study. Here, h_{t,min} is substantially equal to 2 μm, and a structured layer 115 with a thickness hₜ equal to 2.6 μm is selected.

A second step of determining a target width Wo of the coupling section 120.1 will now be described.

FIG. 3 shows the change in the effective refractive indices of the first fundamental optical mode (curve C1), of the second fundamental optical mode (curve C0), and of antisymmetric (curve C3) and symmetric (curve C2) supermodes, as a function of W in μm. For any thickness of the structured layer 115 strictly greater than h_{t,min}, it was found that the curves C0 and C1 frame the curve C3 and intersect it for a single W value equal to Wₘᵢₙ. This is shown in FIG. 3 for the thickness hₜ of 2.6 μm. Thus, for any width W of the ridge greater than or equal to Wₘᵢₙ, photons generated by stimulated emission in the active region 135 can excite an antisymmetric mode that is guided by the guiding structure comprising the main waveguide 120 and the gain medium 130. Here, Wₘᵢₙ is equal to 2.3 μm. The stimulated emission excites the antisymmetric supermode, rather than the symmetric supermode, because the effective refractive index of the antisymmetric supermode is closer to the effective refractive index of the second fundamental optical mode, than the effective refractive index of the symmetric supermode.

This is confirmed by the simulation results in FIG. 4. In this figure, the confinement factor in the active region 135 of the symmetric supermode (curve C10) and the antisymmetric supermode (curve C11) is shown, as a function of W in μm. Note that the curves intersect at Wₘᵢₙ. The confinement factor of the antisymmetric supermode is strictly greater than that of the symmetric supermode for any ridge width W strictly greater than Wₘᵢₙ. Thus, if the antisymmetric supermode is preferably amplified by the stimulated emission and turns off the symmetric supermode.

The confinement factor of a supermode in the active region 135 is equal to the ratio of the intensity of the portion of the supermode located within the active region 135 to the total intensity of the supermode.

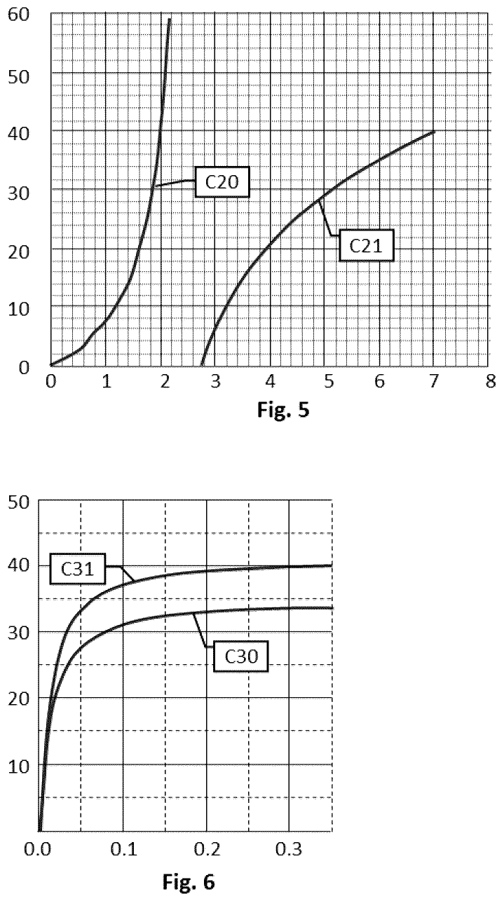

In FIG. 5, the coupling strength Kr of the diffraction grating 125 was calculated for the symmetric supermode (curve C20) and the antisymmetric supermode (curve C21), as a function of W in μm. Here, the teeth of the diffraction grating 125 extend perpendicular to the X axis over the entire width W of the coupling section 120.1. For this calculation, the depth hᵣ is large enough for the evanescent portion of the antisymmetric supermode not to couple to the main waveguide 120 between two teeth of the diffraction grating 125. Here, hᵣ is equal to h_{c}.

The coupling strength Kᵣ of a grating is a measure of the energy transfer from a propagating mode or supermode diffracted by the grating to a counter-propagating mode or supermode resulting from the diffraction, per unit of length. Kᵣ is given by the formula:

$${K}_{r} = \frac{2 Δ {n}_{eff}}{λ} ,$$

where Δn_{eff} is equal to the difference in effective refractive indices of the mode or supermode at one tooth of the grating and between two teeth of the grating. Thus, Kᵣ increases as W or hᵣ increases.

In the context of the DFB quantum cascade laser, Kᵣ is related to the reflectivity Rr of the diffraction grating 125 by the relationship Rᵣ=tanh²(KᵣLᵣ), where Lᵣ is the half-length of the diffraction grating 125 measured parallel to the X-axis. A DFB quantum cascade laser is considered to be sufficiently effective or to have sufficient output, if Rᵣ is between 0.65 and 0.8, which corresponds to a product Kᵣ.Lᵣ between 1 and 1.4.

It is considered that a half-length Lᵣ of the diffraction grating 125 between 0.5 mm and 1 mm gives a sufficiently compact quantum cascade laser 1. For a half-length Lᵣ equal to 0.5 mm, it is therefore preferable to choose values for W and hᵣ that result in a coupling strength Kᵣ between 20 cm⁻¹ and 28 cm⁻¹. For a half-length L, equal to 1 mm, it is preferable to choose values for W and hᵣ that result in a coupling strength Kr between 10 cm⁻¹ and 14 cm⁻¹.

In the second step, FIG. 5 is used to determine the target width W₀ of the coupling section 120.1 within the range of values [Wₘᵢₙ, Wₘₐₓ] previously established, making it possible to obtain a predefined target coupling strength K_{r,0}. In the specific example of FIG. 5, a value W between 3.2 μm (Kᵣ=10 cm⁻¹) and 4.8 μm (Kᵣ=28 cm⁻¹) results in a target coupling strength K_{r,0} making it possible to obtain a compact and efficient quantum cascade laser 1.

A third step of determining a target tooth depth h_{r,0} of the diffraction grating 125 will be described.

FIG. 6 shows the coupling strength Kᵣ (y-axis, in cm−1) as a function of the depth hᵣ of the teeth of the diffraction grating 125 (x-axis, in μm), for W equal to 5.75 μm (curve C30) and W equal to 7 μm (curve C31). Curves C30 and C31 are increasing. It was found that the coupling strength Kᵣ tends asymptotically towards a maximum value K_{r,max} when hᵣ increases. More precisely, the increase in Kᵣ remains contained within an acceptable range of variation beyond a minimum tooth depth h_{r,min}, independent of the width W of the ridge of the coupling section 120.1. The acceptable range of variation is determined to ensure compliance with a specification of a parameter of the quantum cascade laser 1. The specification may be a range of variation of the reflectivity of the diffraction grating 125 to be complied with, for example equal to 2%.

The value of h_{r,min} is then identified, and a target tooth depth h_{r,0} strictly greater than h_{r,min} is determined. Preferably, the difference between h_{r,0} and h_{r,min} is greater than a depth uncertainty associated with an etching process used to form the diffraction grating 125, preferably twice the uncertainty. The minimum tooth depth may depend on several factors, including the wavelength A and the thickness of the lower semiconductor portion 132.

In this example, h_{r,min} is equal to 100 nm, making it possible to keep the increase in the coupling strength Kᵣ below 20% of its value for a tooth depth equal to h_{r,min} in order to guarantee sufficient reflectivity of the diffraction grating 125. The target tooth depth h_{r,0} is, for example, selected to be equal to 180 nm.

The inventors verified that a variation in the tooth depth hᵣ has substantially no influence on the results obtained in FIGS. 3 and 4, as long as hᵣ is greater than h_{r,min}. Thus, it is not necessary to adjust the value of the target width W₀ established in the second step, since the coupling strengths in FIG. 5 have been established for a tooth depth greater than or equal to h_{r,min}.

In a fourth step, using conventional sub-steps from the integrated photonics industry, the quantum cascade laser is manufactured so as to produce a coupling section 120.1 with a width W₀ and a diffraction grating 125 comprising teeth with a depth h_{r,0}, within manufacturing uncertainties.

One of the sub-steps comprises direct bonding of a stack of semiconductor layers comprising elements from columns III and V of the periodic table of elements, onto the structured layer 115. At least one part of the stack is intended to be the gain medium 130 of the quantum cascade laser 1. The choice of exciting an antisymmetric supermode of the guiding structure means that a width W of the coupling section 120.1 is large enough so that the operation of the quantum cascade laser 1 is not impacted by any uncertainty in the alignment of the stack with respect to the structured layer 115, during this direct bonding sub-step.

The width W of the coupling section 120.1 is also large enough to establish efficient heat transfer from the gain medium 130 to the main waveguide 120, when the quantum cascade laser 1 is in operation.

The inventors found that the greater the width W of the coupling section 120.1, the less uncertainty in the value of W resulting from the manufacture of the quantum cascade laser 1 is likely to impact the coupling strength Kr of the antisymmetric supermode with the diffraction grating 125. In all cases, a variation in the width W induces a smaller error in the coupling strength Kᵣ obtained relative to the target coupling strength K_{r,0} with a guiding structure configured to guide an antisymmetric supermode, compared to a guiding structure configured to guide a symmetric supermode.

Finally, since the width W of the coupling section 120.1 is large and the antisymmetric supermode is of the TM type, the latter is only slightly diffracted by the roughness of the sides of the coupling section 120.1. This makes it possible to reduce intra-cavity losses of the quantum cascade laser 1.

Specific embodiments have just been described. Different variants and modifications will become apparent to the person skilled in the art.

1. A quantum cascade laser for emitting a transverse magnetic polarized optical mode at a wavelength λ between 3 μm and 15 μm, comprising:
a semiconductor gain medium comprising an active region,
a main waveguide extending parallel to the active region and comprising:
a coupling section in contact with the gain medium, comprising a diffraction grating configured to generate distributed feedback in the gain medium at the wavelength λ,
a propagation section separated from the gain medium, configured to guide the optical mode,
a guiding structure comprising the gain medium and the main waveguide,
wherein the quantum cascade laser is such that
the coupling section has a width W greater than or equal to a minimum width Wₘᵢₙ from which an antisymmetric supermode propagating in the guiding structure, has a confinement factor in the active region strictly greater than the confinement factors in the active region of the optical modes likely to be guided by the guiding structure,
the main waveguide comprises a core made of a material based on Group IV A atoms of the Periodic Table of Elements and a silicon nitride or chalcogenide confinement sublayer, on a side of the main waveguide opposite to the gain medium.

2. A quantum cascade laser according to claim 1, wherein the main waveguide further comprises a modal transition section in contact with the gain medium, extending from the coupling section to the propagation section, gradually narrowing from the coupling section to the propagation section to cause a modal conversion between the antisymmetric supermode and the optical mode.

3. A quantum cascade laser according to claim 1, wherein the gain medium comprises a lower semiconductor portion in contact with the main waveguide and an upper semiconductor portion, both N-doped, wherein the active region is interposed between the lower and upper semiconductor portions.

4. A quantum cascade laser according to claim 3, wherein the active region and the upper semiconductor portion each and together have rectangular parallelepiped shapes.

5. A quantum cascade laser according to claim 1, wherein the diffraction grating comprises teeth, each having a depth hr, wherein the width W and the depth hᵣ are such that the diffraction grating has a coupling strength Kᵣ between 5 cm⁻¹ and 100 cm⁻¹.

6. A quantum cascade laser according to claim 5, wherein the coupling strength Kᵣ is between 10 cm⁻¹ and 28 cm⁻¹.

7. A quantum cascade laser according to claim 1, wherein the diffraction grating comprises teeth, each having a depth hᵣ, wherein the depth hᵣ is greater than a minimum depth h_{r,min} enabling a variation of a coupling strength Kᵣ of the diffraction grating as a function of hᵣ to be contained within an acceptable variation range determined to guarantee compliance with a specification of the quantum cascade laser.

8. A gas sensor comprising a photonic chip, a chamber optically coupled to the photonic chip, the photonic chip comprising a quantum cascade laser according to claim 1, integrated into the photonic chip.

9. A gas sensor according to claim 8, wherein the quantum cascade laser is an element of an array of a plurality of quantum cascade lasers, wherein each quantum cascade laser of the array is configured to emit an optical mode at a wavelength λᵢ different from the wavelengths of the optical modes emitted by the other quantum cascade lasers of the array.

10. A gas sensor according to claim 9, wherein the photonic chip comprises a wavelength multiplexer and a structured layer, and wherein the gas sensor is such as:
each propagation section of a quantum cascade laser of the array is optically connected to a separate input of the multiplexer,
the multiplexer comprises an output waveguide optically coupled to each of the inputs of the multiplexer, and to the chamber,
the structured layer comprises the multiplexer, the output waveguide and each of the main waveguides of the quantum cascade lasers of the array.

11. A gas sensor according to claim 10, wherein the structured layer further comprises at least a portion of the chamber.

12. A gas sensor according to claim 8, wherein the chamber is a differential Helmholtz resonant photoacoustic cell.
